(19) United States
(12) Patent Application Publication
(10) Pub. No.: US 2024/0368026 A1
(43) Pub. Date: Nov. 7, 2024

(54) PHOTOSENSITIVE INSULATING PASTE AND ELECTRONIC COMPONENT

(71) Applicant: Murata Manufacturing Co., Ltd., Kyoto-fu (JP)

(72) Inventor: Kenta KONDO, Nagaokakyo-shi (JP)

(73) Assignee: Murata Manufacturing Co., Ltd., Kyoto-fu (JP)

(21) Appl. No.: 18/607,740

(22) Filed: Mar. 18, 2024

(30) Foreign Application Priority Data
May 1, 2023 (JP) 2023-075785

(51) Int. Cl. C03C 8/14; C03C 8/08; G03F 7/028; H01F 17/00; H01F 27/32

(52) U.S. Cl. CPC C03C 8/14; C03C 8/08; G03F 7/028; H01F 17/0013; H01F 27/323; C03C 2207/00

(57) ABSTRACT

A photosensitive insulating paste contains glass frit, a first inorganic filler, a second inorganic filler, an alkali-soluble polymer, a photosensitive monomer, a photopolymerization initiator, and a solvent. The glass frit contains SiO₂ and B₂O₃ as a base component and contains at least one of the aluminum element, sodium element, or phosphorus element as a minor component. The first inorganic filler is a silicon oxide having crystallinity, and the second inorganic filler contains at least one of alumina, titania, zirconia, ceria, forsterite, or an inorganic oxide pigment. The photosensitive insulating paste contains the first inorganic filler in an amount of from 10% by volume to 40% by volume and the second inorganic filler in an amount of from 0% by volume to 30% by volume, with the total of the glass frit, the first inorganic filler, and the second inorganic filler being 100% by volume.

### CROSS-REFERENCE TO RELATED APPLICATION

This application claims benefit of priority to Japanese Patent Application No. 2023-075785, filed May 1, 2023, the entire content of which is incorporated herein by reference.

### BACKGROUND

### Technical Field

The present disclosure relates to a photosensitive insulating paste and an electronic component.

### Background Art

In the related art, photosensitive insulating pastes have been used for the formation of inductor components. For example, in Japanese Unexamined Patent Application Publication No. 2012-246176, a photosensitive insulating paste is described that contains silicon oxide, bismuth oxide, boron oxide, aluminum oxide, and zirconium oxide as glass frit in an amount of 50% by mass or more and 90% by mass or less (i.e., from 50% by mass to 90% by mass).

### SUMMARY

With the photosensitive insulating paste described in the above publication, resolution was increased. The difference between the coefficient of linear expansion of insulating layers formed from the photosensitive insulating paste and the coefficient of linear expansion of coil wires, however, was large, occasionally resulting in the occurrence of defects such as cracks. The dielectric constant of the insulating layers, furthermore, was high, leading to the necessity for increasing the thickness of the insulating layers. In such cases, it has not been easy to increase the number of coil wires.

Accordingly, the present disclosure provides a photosensitive insulating paste with a good balance between resolution, dielectric constant, and the coefficient of linear expansion and an electronic component made with the photosensitive insulating paste.

A photosensitive insulating paste that is an aspect of the present disclosure contains glass frit, a first inorganic filler, a second inorganic filler, an alkali-soluble polymer, a photosensitive monomer, a photopolymerization initiator, and a solvent, wherein the glass frit contains SiO₂ and B₂O₃ as a base component and contains at least one of aluminum element, sodium element, or phosphorus element as a minor component; the first inorganic filler is a silicon oxide having crystallinity. The second inorganic filler contains at least one of alumina, titania, zirconia, ceria, forsterite, or an inorganic oxide pigment. The photosensitive insulating paste contains the first inorganic filler in an amount of 10% by volume or more and 40% by volume or less (i.e., from 10% by volume to 40% by volume) and the second inorganic filler in an amount of 0% by volume or more and 30% by volume or less (i.e., from 0% by volume to 30% by volume), with a total of the glass frit, the first inorganic filler, and the second inorganic filler being 100% by volume.

By incorporating the glass frit, the first filler, and the second filler within the ranges specified above, it is possible to form a photosensitive insulating paste with a good balance between resolution, dielectric constant, and the coefficient of linear expansion.

In a form of the photosensitive insulating paste, a softening point of the glass frit is 700° C. or above and below 900° C. (i.e., from 700° C. to below 900° C.).

With this configuration, the glass frit melts at a temperature lower than the sintering temperature of the metal material for the coil wires that the inductor component contains. The adhesion between the body, which is formed from the photosensitive insulating paste containing the glass frit, and the coil wires, therefore, is good.

In a form of the photosensitive insulating paste, the photosensitive insulating paste contains the first inorganic filler in an amount of 20% by volume or more and 40% by volume or less (i.e., from 20% by volume to 40% by volume) and the second inorganic filler in an amount of 0% by volume or more and 20% by volume or less (i.e., from 0% by volume to 20% by volume), with the total of the glass frit, the first inorganic filler, and the second inorganic filler being 100% by volume.

By incorporating the first inorganic filler and the second inorganic filler within the ranges specified above, it is possible to increase the strength of the body. At the same time, the reliability of the inductor component improves because the difference between the coefficient of linear expansion of the body and that of the metal material becomes smaller. The dielectric constant of the body is also reduced. The balance between resolution, dielectric constant, and the coefficient of linear expansion, therefore, becomes better.

In a form of the photosensitive insulating paste, the photosensitive insulating paste contains the first inorganic filler in an amount of 30% by volume or more and 40% by volume or less (i.e., from 30% by volume to 40% by volume) and the second inorganic filler in an amount of 10% by volume or more and 20% by volume or less (i.e., from 10% by volume to 20% by volume), with the total of the glass frit, the first inorganic filler, and the second inorganic filler being 100% by volume.

Through the incorporation of the first inorganic filler within the range specified above, the coefficient of linear expansion of the body, which is formed from the photosensitive insulating paste, increases. This helps reduce the difference between the coefficient of linear expansion of the body and that of the metal material, thereby helping reduce the formation of cracks. Through the incorporation of the second inorganic filler within the range specified above, the strength of the body increases. This leads to a further improvement in the reliability of the inductor component.

In a form of the photosensitive insulating paste, the minor component of the glass frit includes the phosphorus element.

With this configuration, the melting point of the glass frit becomes relatively low, and the coefficient of linear expansion increases. This helps reduce the difference between the coefficient of linear expansion of the coil wires and that of the body. The development of stress caused by the difference in the coefficient of linear expansion, furthermore, is reduced, helping reduce the formation of cracks.

In a form of the photosensitive insulating paste, the phosphorus element is contained in an amount of 0.1% by mass or more and 10% by mass or less (i.e., from 0.1% by mass to 10% by mass).

With this configuration, the difference between the coefficient of linear expansion of the coil wires and that of the body is further reduced. The development of stress caused by the difference in the coefficient of linear expansion, furthermore, is further reduced, helping further reduce the formation of cracks.

An electronic component that is an aspect of the present disclosure includes a body; and a coil disposed inside the body and wound along an axis, wherein the coil includes multiple coil wires; the body contains a glass material, a first inorganic filler, and a second inorganic filler; and the glass material contains SiO₂ and B₂O₃ as a base component and contains at least one of aluminum element, sodium element, or phosphorus element as a minor component; the first inorganic filler is a silicon oxide having crystallinity; the second inorganic filler contains at least one of alumina, titania, zirconia, ceria, forsterite, or an inorganic oxide pigment. Also, the body contains the first inorganic filler in an amount of 10% by volume or more and 40% by volume or less (i.e., from 10% by volume to 40% by volume) and the second inorganic filler in an amount of 0% by volume or more and 30% by volume or less (i.e., from 0% by volume to 30% by volume), with a total of the glass material, the first inorganic filler, and the second inorganic filler being 100% by volume.

By incorporating the glass material, the first inorganic filler, and the second inorganic filler within the ranges specified above, it is possible to form a body with a good balance between resolution, dielectric constant, and the coefficient of linear expansion.

In a form of the electronic component, a ratio of a thickness of the coil wires in a direction along the axis to a thickness of portions of the body between adjacent ones of the coil wires in the direction along the axis is in a range of 1.0 or greater and 3.0 or less (i.e., from 1.0 to 3.0).

With this configuration, the thickness of the portions of the body between adjacent coil wires becomes smaller. As a result, it becomes possible to increase the number of coil wires and thereby to increase the inductance value. When the above ratio is too low, the thickness of the portions of the body between adjacent coil wires is large. The number of coil wires, therefore, is small, and the number of windings in the coil is small. As a result, the inductance value (L value) of the electronic component is small. When the above ratio is too high, the thickness of the portions of the body between adjacent coil wires is too small. In that case the coil wires come within a short distance, potentially causing a large stray capacitance and a decrease in Q value.

In this context, the thickness of the portions of the body between adjacent coil wires in the direction along the axis is the value of the shortest distance between adjacent coil wires in the cross-section that passes through the center of the body and is perpendicular to the direction in which the coil wires extend. The thickness of the coil wires in the direction along the axis is the maximum value of the thickness of the coil wires in the direction along the axis in the cross-section that passes through the center of the body and is perpendicular to the direction in which the coil wires extend.

In a form of the electronic component, an average of a thickness of the coil wires in a direction along the axis is 3 μm or more and 15 μm or less (i.e., from 3 μm to 15 μm).

With this configuration, the direct-current resistance (Rdc) is reduced. It becomes, furthermore, possible to increase the number of coil wires and thereby to increase the inductance value. When the above average is too small, the direct-current resistance is large. When the above average is too large, the number of coil wires is small; in other words, the number of windings in the coil is small. As a result, the inductance value decreases.

In a form of the electronic component, the number of windings of the coil wires is one or more loops.

With this configuration, the inductance value is improved. In particular, owing to a moderate dielectric constant of the body, the increase in stray capacitance is limited even if the coil wires have one or more loops and extend parallel in certain sections. This helps improve the characteristics of the electronic component.

According to the present disclosure, there can be provided a photosensitive insulating paste with a good balance between resolution, dielectric constant, and the coefficient of linear expansion and an electronic component made with the photosensitive insulating paste.

### BRIEF DESCRIPTION OF THE DRAWINGS

FIG. 1 is a top perspective view schematically illustrating an inductor component according to a first embodiment;

FIG. 2 is an exploded perspective view of an inductor component according to the first embodiment;

FIG. 3 is an XY cross-sectional view of an inductor component according to the first embodiment;

FIG. 4A is an explanatory view with which a method for manufacturing an inductor component is described;

FIG. 4B is an explanatory view with which a method for manufacturing an inductor component is described;

FIG. 4C is an explanatory view with which a method for manufacturing an inductor component is described;

FIG. 4D is an explanatory view with which a method for manufacturing an inductor component is described; and

FIG. 4E is an explanatory view with which a method for manufacturing an inductor component is described.

### DETAILED DESCRIPTION

An electronic component that is an aspect of the present disclosure will now be described in detail with the embodiment illustrated in the drawings. It should be noted that some of the drawings are schematic; the dimensions and proportions may be different from reality. While the following description focuses on an inductor component that is an example of an electronic component, furthermore, the electronic component may be an electronic component other than an inductor component.

### First Embodiment

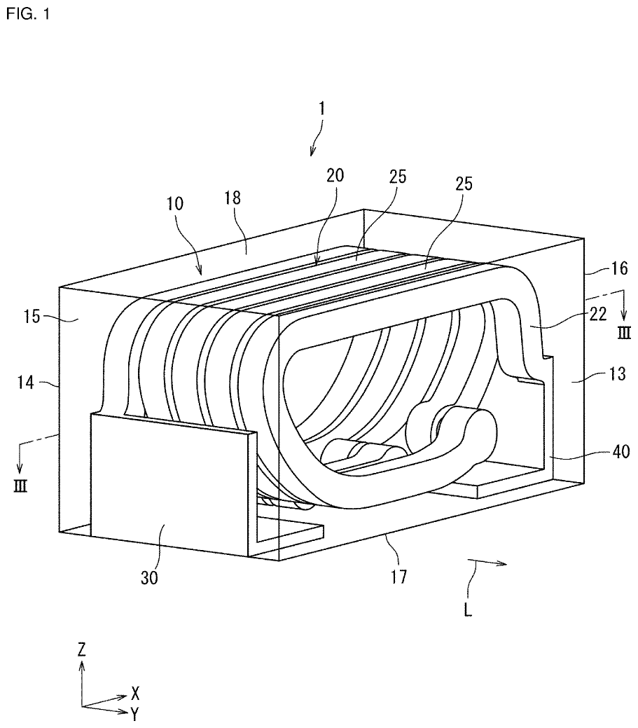

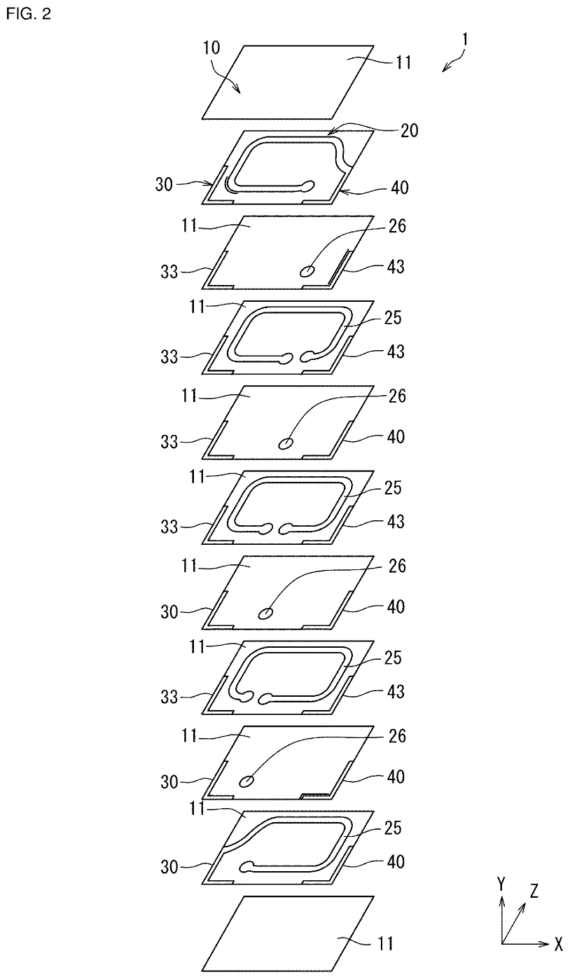

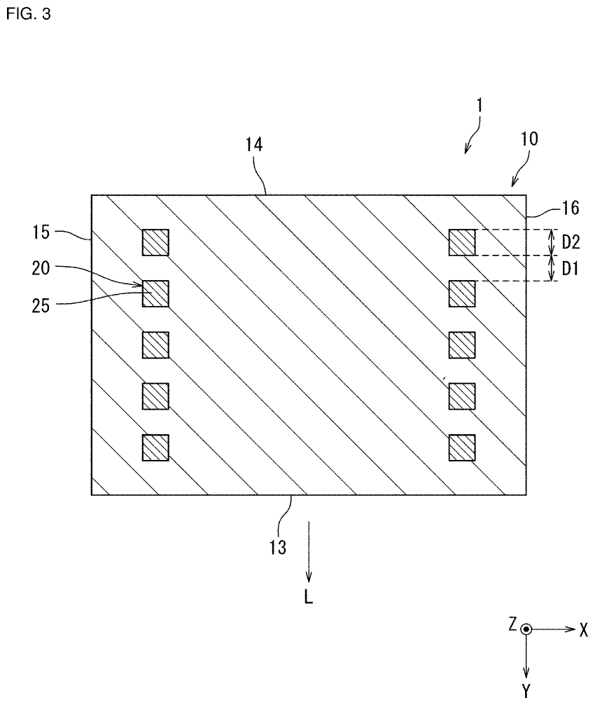

FIG. 1 is a top perspective view schematically illustrating an inductor component according to a first embodiment. FIG. 2 is an exploded perspective view of the inductor component. FIG. 3 is an XY cross-sectional view of the inductor component. Although the body 10 in FIG. 1 is depicted as transparent so that the structure can be easily understood, the body 10 may be translucent or opaque. In FIG. 3, the description of via wires is omitted so that the structure can be easily understood.

The inductor component 1 is electrically coupled to the wiring of a circuit board, not illustrated, through first and second outer electrodes 30 and 40. The inductor component 1 is used as, for example, a coil for impedance matching (matching coil) in radiofrequency circuits and is used in electronic equipment such as PCs, DVD players, digital cameras, TV sets, mobile phones, automotive electronics, and medical and industrial machinery. The applications of the inductor component 1, however, are not limited to these; for example, the inductor component 1 can be used in equipment such as tuned circuits, filter circuits, and rectifier/smoothing circuits.

The body 10 is composed of multiple insulating layers 11 stacked on top of each other. The insulating layers 11 are obtained by, for example, forming a multilayer body by repeating multiple times a step of applying a photosensitive insulating paste and optionally drying the resulting coating and then performing firing. The body 10 is substantially cuboid in shape. The surface of the body 10 has a first side face 13, a second side face 14 facing the first side face, a first end face 15, a second end face 16 facing the first end face 15, a bottom face 17 connecting between the first end face 15 and the second end face 16, and a top face 18 facing the bottom face 17. The first end face 15, second end face 16, bottom face 17, and top face 18 are surfaces parallel to the direction of stacking of the insulating layers 11. It should be noted that “parallel” as used herein is not limited to a strictly parallel relationship and includes relationships that are substantially parallel considering a realistic range of variations. In addition, the body 10 may have, for example as a result of firing, unclear interfaces between the multiple insulating layers 11.

As illustrated in the drawings, the direction from the first end face 15 toward the second end face 16 is hereinafter referred to as the X direction for the convenience of description. The direction from the second side face 14 toward the first side face 13 is referred to as the Y direction. The direction from the bottom face 17 toward the top face 18 is referred to as the Z direction. The X, Y, and Z directions are directions perpendicular to each other. When arranged in the order of X, Y, and then Z, they form a left-hand coordinate system.

The first outer electrode 30 and the second outer electrode 40 are composed of, for example, a conductive material, such as Ag or Cu, and glass particles. The first outer electrode 30 is in an L-shape provided to span the first end face 15 and the bottom face 17. The second outer electrode 40 is in an L-shape provided to span the second end face 16 and the bottom face 17. It should be noted that the first outer electrode 30 and the second outer electrode 40 in the first embodiment have an L-shape, but the outer electrodes may have another shape. For example, the first outer electrode 30 and the second outer electrode 40 may have a shape in which they are provided only at the bottom face. Alternatively, the first outer electrode 30 may be provided at the first end face 15 of the body 10 and part of the first side face 13, second side face 14, bottom face 17, and top face 18, which are adjacent to the first end face 15, and the second outer electrode 40 may be provided at the second end face 16 and part of the first side face 13, second side face 14, bottom face 17, and top face 18, which are adjacent to the second end face 16.

The coil 20 is composed of, for example, a conductive material and glass particles similar to those for the first and second outer electrodes 30 and 40. The coil 20 is wound in a helical shape along the direction of stacking of the insulating layers 11. A first end of the coil 20 is coupled to the first outer electrode 30, and a second end of the coil 20 is coupled to the second outer electrode 40. It should be noted that the coil 20 and the first and second outer electrodes 30 and 40 in this embodiment constitute a one-piece structure without a clear boundary therebetween, but these elements are not limited to this; there may be a boundary between the coil and outer electrodes as a result of being formed from different materials or by different processes.

The coil 20 is substantially in an elongated round shape as viewed in the direction L along its axis but is not limited to this shape. The shape of the coil 20 may be, for example, round, oval, rectangular, or other polygonal shapes. The direction L along the axis of the coil 20 refers to the direction parallel to the central axis of the helix in which the coil 20 is wound. The direction L along the axis of the coil 20 and the direction of stacking of the insulating layers 11 refer to the same direction (Y direction).

The coil 20 includes multiple coil wires 25 wound on the insulating layers 11. Coil wires 25 adjacent in the stacking direction are electrically coupled in series, with a via wire 26 that extends through an insulating layer 11 in the thickness direction interposed therebetween. In such a manner, the multiple coil wires 25 form a helix while being electrically coupled to each other in series. Specifically, the coil 20 has a structure in which multiple coil wires 25 that are electrically coupled to each other in series and in which the number of windings is less than one loop are stacked on top of each other, and the coil 20 is in a helical shape. It should be noted that the number of windings in the coil 20 may be one or more loops, and less than one loop and one or more loops may be combined.

Preferably, the ratio of the thickness D2 of the coil wires 25 in the direction L along the axis to the thickness D1 of the portions of the body 10 between adjacent coil wires 25 in the direction L along the axis is in the range of 1.0 or greater and 3.0 or less (i.e., from 1.0 to 3.0). With this configuration, thickness D1 becomes smaller. As a result, it becomes possible to increase the number of coil wires 25 and thereby to increase the inductance value. When this ratio is too low, thickness D1 is large. The number of coil wires 25, therefore, is small, and the number of windings in the coil 20 is small. As a result, the inductance value of the inductor component 1 is small. When this ratio is too high, thickness D1 is too small. In that case the coil wires 25 come within a short distance, potentially causing a large stray capacitance and a decrease in Q value.

In this context, thickness D1 is the value of the shortest distance between adjacent coil wires 25 in the cross-section that passes through the center of the body 10 and is perpendicular to the direction in which the coil wires 25 extend. Thickness D2 is the maximum value of the coil wires 25 in the direction L along the axis in the cross-section that passes through the center of the body 10 and is perpendicular to the direction in which the coil wires 25 extend.

Preferably, the average of the thickness of the coil wires 25 in the direction L along the axis is 3 μm or more and 15 μm or less (i.e., from 3 μm to 15 μm). With this configuration, the direct-current resistance (Rdc) is reduced. It becomes, furthermore, possible to increase the number of coil wires 25 and thereby to increase the inductance value (L value). When this average is too small, the direct-current resistance is large. When this average is too large, the number of coil wires 25 is small; in other words, the number of windings in the coil 20 is small. As a result, the inductance value decreases.

Preferably, the number of windings of the coil wires 25 is one or more loops. With this configuration, the inductance value of the inductor component 1 is improved. In particular, owing to a moderate dielectric constant of the body 10, the increase in stray capacitance is limited even if the coil wires 25 have one or more loops and extend parallel in certain sections. This helps improve the characteristics of the inductor component 1.

### Photosensitive Insulating Paste and Insulating Layers 11

The photosensitive insulating paste and the insulating layers 11 will be described.

The photosensitive insulating paste contains glass frit, a first inorganic filler, a second inorganic filler, at least one alkali-soluble polymer, a photosensitive monomer, a photopolymerization initiator, and a solvent. The glass frit contains SiO₂ and B₂O₃ as its base component and contains at least one of the aluminum element, the sodium element, or the phosphorus element as its minor component. The first inorganic filler is a silicon oxide having crystallinity. The second inorganic filler contains at least one of alumina, titania, zirconia, ceria, forsterite, or an inorganic oxide pigment. The photosensitive insulating paste contains the first inorganic filler in an amount of 10% by volume or more and 40% by volume or less (i.e., from 10% by volume to 40% by volume) and the second inorganic filler in an amount of 0% by volume or more and 30% by volume or less (i.e., from 0% by volume to 30% by volume), with the total of the glass frit, the first inorganic filler, and the second inorganic filler being 100% by volume.

Through research by the inventor, it was found that by incorporating the glass frit, the first inorganic filler, and the second inorganic filler within the ranges specified above, it is possible to form a photosensitive insulating paste with a good balance between resolution, dielectric constant, and the coefficient of linear expansion. Specifically, by incorporating the glass frit within the range specified above, a photosensitive insulating paste with high resolution is obtained. With this photosensitive insulating paste, high-precision inductor components 1 can be formed. When the percentage of the glass frit is high, the effect of the fillers contained in the body 10 (insulating layers 11), which is formed from the photosensitive insulating paste, in preventing crack growth can be lost. In that case the strength can decrease, potentially causing cracks in the body 10. When the percentage of the glass frit is low, the glass frit cannot be densely fired. As a result, the body 10 is brittle and prone to breakage. Through the incorporation of the first inorganic filler within the above range, it becomes possible to sinter the body 10 densely. At the same time, the difference in the coefficient of linear expansion between the body 10 and the metal material for coil wires 25 that the above inductor component 1 contains is reduced, helping reduce the formation of cracks. The dielectric constant of the body 10, furthermore, is reduced, helping improve the electrical characteristics of the inductor component 1. It should be noted that when the percentage of the first inorganic filler is too high, the percentage of the glass frit is low. In that case the glass frit cannot be densely sintered, resulting in brittleness in the body 10. When the percentage of the first filler is too low, furthermore, the aforementioned effects, a reduced difference in the coefficient of linear expansion and a reduced dielectric constant, are lost. By adding the second inorganic filler, it is possible to further increase the strength of the body 10 and thereby to allow the body 10 to withstand the stress that occurs between the body 10 and the coil wires 25. As a result, through the incorporation of the second inorganic filler within the range specified above, the likelihood of cracks occurring decreases. When the percentage of the second inorganic filler is too high, the optical transparency of the photosensitive paste decreases, and resolution degrades. The body 10, furthermore, is unlikely to sinter densely and thus is brittle. In addition to these, the dielectric constant of the body 10 increases, and the electrical characteristics of the inductor component 1 deteriorate. By incorporating the glass frit, the first inorganic filler, and the second inorganic filler within the ranges specified above, furthermore, the thickness of the body 10 can be reduced. The number of coil wires 25 can be increased, and, as a result, the inductance value of the inductor component 1 increases. Additionally, through the incorporation of the glass frit, the first inorganic filler, and the second inorganic filler within the ranges specified above, the dielectric constant of the body 10 decreases. Owing to this, the thickness of the portions of the body 10 between adjacent coil wires 25 can be reduced. The number of coil wires 25 can be increased, and as a result, the inductance value of the inductor component 1 increases. Overall, by incorporating the glass frit, the first inorganic filler, and the second inorganic filler within the ranges specified above, it is possible to form a body 10 with a good balance between resolution, dielectric constant, and the coefficient of linear expansion.

The glass frit can be borosilicate glass. Instead of borosilicate glass, the glass frit may be glass that contains, for example, SiO₂, B₂O₃, K₂O, Li₂O, CaO, ZnO, Bi₂O₃, P₂O₅, and/or Al₂O₃, such as SiO₂—B₂O₃—K₂O glass, SiO₂—B₂O₃—Li₂O—CaO glass, SiO₂—B₂O₃—Li₂O—CaO—ZnO glass, SiO₂—B₂O₃—P₂O₅ glass, or Bi₂O₃—B₂O₃—SiO₂—Al₂O₃ glass. For these inorganic components, two or more may be combined.

The softening point of the glass frit is 700° C. or above and below 900° C. (i.e., from 700° C. to below 900° C.). With this configuration, the glass frit melts at a temperature lower than the sintering temperature of the metal material for the coil wires 25 that the inductor component 1 contains. The adhesion between the body 10, which is formed from a photosensitive insulating paste containing the glass frit, and the coil wires 25, therefore, is good. The softening point is a value measured using a thermomechanical analyzer (TMA).

Examples of first inorganic fillers include quartz and silica. Preferably, quartz can be used. With this configuration, the coefficient of linear expansion increases, and the difference in the coefficient of linear expansion between the insulating layers 11, which are formed from the photosensitive insulating paste, and the coil wires 25 further decreases. Through this, the formation of cracks between the insulating layers 11 and the coil wires 25 can be reduced. The quartz is crystallized quartz, and the degree of crystallization of the quartz is not particularly limited.

Preferably, the second inorganic filler is alumina.

The average particle size of each of the first inorganic filler and the second inorganic filler is, for example, 0.1 μm or more and 5.0 μm or less (i.e., from 0.1 μm to 5.0 μm), specifically 0.3 μm or more and 3.0 μm or less (i.e., from 0.3 μm to 3.0 μm). When the average particle size is too small, the dispersion of the photosensitive insulating paste is difficult. When the average particle size is too large, the smoothness of the insulating layers 11 can decrease.

The alkali-soluble polymer includes, for example, an acrylic copolymer having a carboxyl group at its side chain. The resin including an acrylic copolymer having a carboxyl group at its side chain can be produced by, for example, copolymerizing an unsaturated carboxylic acid and an ethylenically unsaturated compound.

Examples of unsaturated carboxylic acids include acrylic acid, methacrylic acid, maleic acid, fumaric acid, and vinylacetic acid and their anhydrides. Examples of ethylenically unsaturated compounds include acrylates, such as methyl acrylate and ethyl acrylate, methacrylates, such as methyl methacrylate and ethyl methacrylate, and fumarates, such as monoethyl fumarate.

The acrylic copolymer having a carboxyl group at its side chain may be one into which an unsaturated bond has been introduced, as in the following forms.

(1) To the carboxyl group at a side chain of the acrylic copolymer, an acrylic monomer having a functional group that can react with it, such as an epoxy group, is added.

(2) An unsaturated monocarboxylic acid is allowed to react with the acrylic copolymer into which an epoxy group has been introduced instead of the carboxyl group at a side chain. Then a saturated or unsaturated polycarboxylic anhydride is further introduced.

The acrylic copolymer having a carboxyl group at its side chain may be one having a weight-average molecular weight (Mw) of 50,000 or less and an acid value of 30 or more and 150 or less (i.e., from 30 to 150).

The photosensitive monomer can be dipentaerythritol monohydroxypentaacrylate. Besides dipentaerythritol monohydroxypentaacrylate, compounds such as hexanediol triacrylate, tripropylene glycol triacrylate, trimethylolpropane triacrylate, EO-modified trimethylolpropane triacrylate, stearyl acrylate, tetrahydrofurfuryl acrylate, lauryl acrylate, 2-phenoxyethyl acrylate, isodecyl acrylate, isooctyl acrylate, tridecyl acrylate, caprolactone acrylate, ethoxylated nonylphenol acrylate, 1,3-butanediol diacrylate, 1,4-butanediol diacrylate, diethylene glycol diacrylate, tetraethylene glycol diacrylate, triethylene glycol diacrylate, ethoxylated bisphenol A diacrylate, propoxylated neopentyl glycol diacrylate, tris(2-hydroxyethyl)isocyanurate triacrylate, pentaerythritol triacrylate, propoxylated trimethylolpropane triacrylate, propoxylated glyceryl triacrylate, pentaerythritol tetraacrylate, ditrimethylolpropane tetraacrylate, and ethoxylated pentaerythritol tetraacrylate can be used as photosensitive monomers. Variations of these compounds in which a subset or all of the acrylates in the molecule have been changed to methacrylates, furthermore, can be used.

The photopolymerization initiator can be an acetophenone compound, benzophenone compound, acylphosphine compound, or oxime ester compound.

The solvent is not particularly limited. Examples of solvents that can be used include ethylene glycol monobutyl ether, ethylene glycol monohexyl ether, ethylene glycol monoethylhexyl ether, propylene glycol monobutyl ether, dipropylene glycol monoethyl ether, dipropylene glycol monobutyl ether, propylene glycol monophenyl ether, ethyl acetate, butyl acetate, pentyl acetate, hexyl acetate, and cyclohexanol acetate.

The photosensitive insulating paste may further contain an organic dye. The organic dye can be an azo compound. The organic dye functions as an ultraviolet absorber for fine-tuning ultraviolet transmittance when the photosensitive insulating paste is used for photolithographic patterning.

Preferably, the photosensitive insulating paste contains the first inorganic filler in an amount of 20% by volume or more and 40% by volume or less (i.e., from 20% by volume to 40% by volume) and the second inorganic filler in an amount of 0% by volume or more and 20% by volume or less (i.e., from 0% by volume to 20% by volume), with the total of the glass frit, the first inorganic filler, and the second inorganic filler being 100% by volume. By incorporating the first inorganic filler and the second inorganic filler within these ranges, it is possible to increase the strength of the body 10. At the same time, the reliability of the inductor component 1 improves because the difference between the coefficient of linear expansion of the body 10 and that of the metal material becomes smaller. The dielectric constant of the body 10 is also reduced. The balance between resolution, dielectric constant, and the coefficient of linear expansion, therefore, becomes better.

Preferably, the photosensitive insulating paste contains the first inorganic filler in an amount of 30% by volume or more and 40% by volume or less (i.e., from 30% by volume to 40% by volume) and the second inorganic filler in an amount of 10% by volume or more and 20% by volume or less (i.e., from 10% by volume to 20% by volume), with the total of the glass frit, the first inorganic filler, and the second inorganic filler being 100% by volume. Through the incorporation of the first inorganic filler within this range, the coefficient of linear expansion of the body 10, which is formed from the photosensitive insulating paste, increases. This helps reduce the difference between the coefficient of linear expansion of the body 10 and that of the metal material, thereby helping reduce the formation of cracks. Through the incorporation of the second inorganic filler within this range, the strength of the body 10 increases. This leads to a further improvement in the reliability of the inductor component 1.

It should be noted that the photosensitive insulating paste may contain the first inorganic filler in an amount of 10% by volume or more and 40% by volume or less (i.e., from 10% by volume to 40% by volume) and the second inorganic filler in an amount of 0% by volume or may contain the first inorganic filler in an amount of 20% by volume or more and 40% by volume or less (i.e., from 20% by volume to 40% by volume) and the second inorganic filler in an amount of 0% by volume, both with the total of the glass frit, the first inorganic filler, and the second inorganic filler being 100% by volume.

Preferably, the glass frit contains the phosphorus element as a minor component. With this configuration, the melting point of the glass frit becomes relatively low, and the coefficient of linear expansion increases. This helps reduce the difference between the coefficient of linear expansion of the coil wires 25 and that of the body 10. The development of stress caused by the difference in coefficient of linear expansion, furthermore, is reduced, helping reduce the formation of cracks.

Preferably, the glass frit contains the phosphorus element in an amount of 0.1% by mass or more and 10% by mass or less (i.e., from 0.1% by mass to 10% by mass). The amount of the phosphorus element is measured using a wavelength dispersive x-ray fluorescence analyzer (WDX) or inductively coupled plasma (ICP) optical emission spectrometer.

The insulating layers 11 contain a glass material, a first inorganic filler, and a second inorganic filler. The glass material contains SiO₂ and B₂O₃ as its base component and contains at least one of the aluminum element, the sodium element, or the phosphorus element as its minor component. The first inorganic filler is a silicon oxide having crystallinity. The second inorganic filler contains at least one of alumina, titania, zirconia, ceria, forsterite, or an inorganic oxide pigment. The insulating layers 11 contain the first inorganic filler in an amount of 10% by volume or more and 40% by volume or less (i.e., from 10% by volume to 40% by volume) and the second inorganic filler in an amount of 0% by volume or more and 30% by volume or less (i.e., from 0% by volume to 30% by volume), with the total of the glass material, the first inorganic filler, and the second inorganic filler being 100% by volume. In other words, the insulating layers 11 contain the glass material in an amount of 30% by volume or more and 90% by volume or less (i.e., from 30% by volume to 90% by volume), the first inorganic filler in an amount of 10% by volume or more and 40% by volume or less (i.e., from 10% by volume to 40% by volume), and the second inorganic filler in an amount of 0% by volume or more and 30% by volume or less (i.e., from 0% by volume to 30% by volume), with the total of the glass material, the first inorganic filler, and the second inorganic filler being 100% by volume. It should be noted that the base component refers to a component that is contained in an amount of 60% by volume or more, with the amount of the glass material being 100% by volume. There is no specific upper limit, but for example, the amount of the base component is 99% by volume or less. The minor component refers to a component that is contained in an amount of 40% by volume or less, with the amount of the glass material being 100% by volume. There is no specific lower limit, but for example, the amount of the minor component is 0.1% by volume or more. The proportions of the glass material, the first inorganic filler, and the second inorganic filler contained in the insulating layers 11 are substantially the same as the proportions of the glass frit, the first inorganic filler, and the second inorganic filler contained in the photosensitive insulating paste. The glass material contained in the insulating layers 11 is obtained by firing the glass frit contained in the photosensitive insulating paste. The types and composition of the first inorganic filler and second inorganic filler contained in the insulating layers 11 are the same as the types and composition of the first inorganic filler and second inorganic filler contained in the photosensitive insulating paste.

As with the glass frit, first inorganic paste, and second inorganic paste in the photosensitive insulating paste, by incorporating the glass material, the first inorganic paste, and the second inorganic paste within the ranges specified above, it is possible to form insulating layers 11 (body 10) with a good balance between resolution, dielectric constant, and the coefficient of linear expansion.

### Manufacturing Method

A method for manufacturing the inductor component 1 will now be described.

First, a negative photosensitive insulating paste and a conductive paste are prepared.

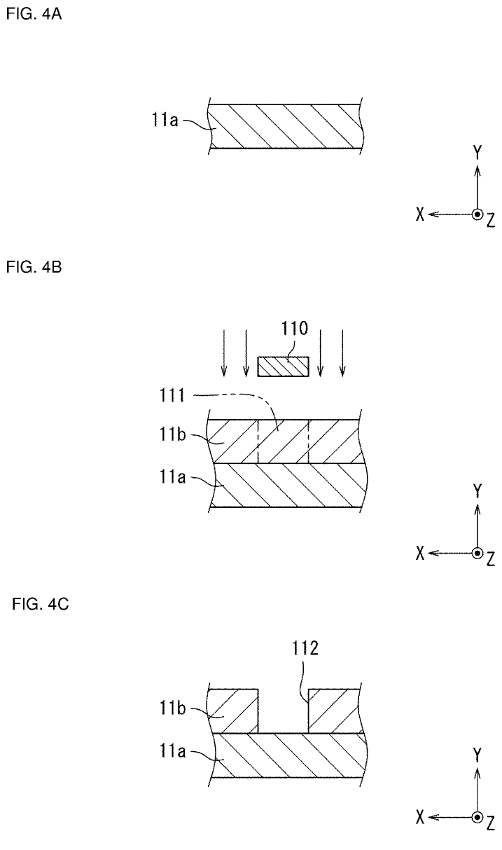

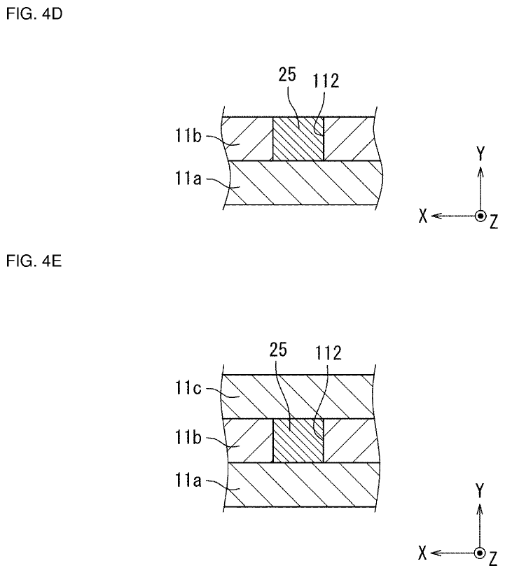

As illustrated in FIG. 4A, the photosensitive insulating paste is applied to form an outer insulating layer 11a. The photosensitive insulating paste is applied by, for example, screen printing. It should be noted that FIGS. 4A to 4E are cross-sectional views in the XY directions.

As illustrated in FIG. 4B, the photosensitive insulating paste is applied to the outer insulating layer 11a to form a first insulating layer 11b. Then the first insulating layer 11b is exposed to light, with a first portion 111 (indicated by long-dashed double-short-dashed lines) of the first insulating layer 11b shaded with a mask 110. As illustrated in FIG. 4C, the first portion 111 of the first insulating layer 11b is removed through development, creating a groove 112 in the position corresponding to the first portion 111. As illustrated in FIG. 4D, the coil wire 25 is formed inside the groove 112.

As illustrated in FIG. 4E, the photosensitive insulating paste is applied onto the first insulating layer 11b and the coil wire 25 to form a second insulating layer 11c. These steps are repeated multiple times to form a multilayer body, and then firing is performed. In this manner, an inductor component 1 is manufactured.

### EXAMPLES

The present disclosure will be described more specifically through the following examples, but the present disclosure is not limited to these examples.

### Examples 1 to 9 and Comparative Examples 1 to 3

By mixing phosphorus element-containing borosilicate glass as the glass frit, quartz as the first inorganic filler, and alumina as the second inorganic filler according to the proportions specified in Table 1, a photosensitive insulating paste was formed.

Using the resulting photosensitive insulating paste, an inductor component 1 was formed. During the formation of the inductor component 1, furthermore, resolution, dielectric constant, and effectiveness in crack prevention were measured. The results are presented in Table 1.

### Resolution

The paste was applied by screen printing to a thickness of 20 m, and the resulting coating was dried in a fail-safe oven. Then the coating was exposed to light through a photomask having openings in different dimensions, and development with an aqueous alkali solution was performed. In this manner, wiring patterns were formed. The width and thickness of a pattern that was produced without residue or pattern breakage were measured, and the aspect ratio (thickness/width) was calculated.
⊚: The resolution is 1.0 or greater.
∘: The resolution is 0.5 or greater and less than 1.0 (i.e., from 0.5 to less than 1.0).
x: The resolution is less than 0.5.

### Dielectric Constant

An insulating layer was formed from the photosensitive insulating paste, and the dielectric constant was measured. The dielectric constant was measured using a signal analyzer (manufactured by Keysight Technologies).
⊚: The dielectric constant is 6.0 or greater.
∘: The dielectric constant is 6.0 or greater and less than 7.0 (i.e., from 6.0 to less than 7.0).
x: The dielectric constant is less than 7.0.

### Effectiveness in Crack Prevention

The effectiveness in crack prevention was measured as follows.

The inductor component prepared from the insulating paste was fixed on a substrate. The measuring indenter of a nanoindentation tester was pressed into the body portion of the inductor component, and a test load (p)-displacement (h) plot during it was obtained. From the obtained test load (p)-displacement (h) data, contact stiffness with increasing load (S=dp/dh) was calculated. A contact stiffness (S)-test load (p) plot was constructed. Of the peaks in the resulting plot at which a decrease in contact stiffness was observed, the peak at the smallest load was considered the first crack that developed in the component's body portion. This load was defined as “cracking load.”

The apparatus and conditions for the measurement with a nanoindentation tester were as follows.
Equipment: ENT-1100a nanoindentation tester (manufactured by ELIONIX Inc.)
Test load: 100 gf
Step interval: 20 msec
⊚: The cracking load is 70 N or more.
∘: The cracking load is 30 N or more and less than 70 N (i.e., from 30 N to less than 70 N).
x: The cracking load is less than 30 N.

TABLE 1

| | | First | Second | | | |
|---|---|---|---|---|---|---|
| | | inorganic | inorganic | | | |
| | Glass frit | filler | filler | | | Effectiveness |
| | (% by | (% by | (% by | | Dielectric | in crack |
| | volume) | volume) | volume) | Resolution | constant | prevention |
| Example 1 | 90 | 10 | 0 | ⊚ | ∘ | ∘ |
| Example 2 | 80 | 20 | 0 | ⊚ | ⊚ | ∘ |
| Example 3 | 70 | 30 | 0 | ⊚ | ⊚ | ∘ |
| Example 4 | 60 | 40 | 0 | ⊚ | ⊚ | ∘ |
| Example 5 | 50 | 40 | 10 | ⊚ | ⊚ | ⊚ |
| Example 6 | 50 | 30 | 20 | ⊚ | ⊚ | ⊚ |
| Example 7 | 50 | 20 | 30 | ∘ | ∘ | ⊚ |
| Example 8 | 40 | 30 | 30 | ∘ | ∘ | ⊚ |
| Example 9 | 30 | 40 | 30 | ∘ | ∘ | ⊚ |
| Comparative | 100 | 0 | 0 | ⊚ | ∘ | x |
| Example 1 | | | | | | |
| Comparative | 20 | 40 | 40 | x | x | x |
| Example 2 | | | | | | |
| Comparative | 20 | 50 | 30 | ∘ | ∘ | x |
| Example 3 | | | | | | |

In Examples 1 to 4, a photosensitive insulating paste containing the glass frit and the first inorganic filler were used. In Examples 1 to 4, the resolution of the photosensitive insulating paste, dielectric constant, and effectiveness in crack prevention were all good. In particular, through the incorporation of the first inorganic filler in an amount of 2000 by volume or more and 4000 by volume or less (i.e., from 20% by volume to 40% by volume), the dielectric constant became even better.

In Examples 5 to 9, a photosensitive insulating paste containing the glass frit, the first inorganic filler, and the second inorganic filler was used. In Examples 5 to 9, the resolution of the photosensitive insulating paste, dielectric constant, and effectiveness in crack prevention were all good. In particular, Examples 5 to 9 were better than Examples 1 to 4 in terms of effectiveness in crack prevention. This is presumably because the strength of the body improved through the incorporation of the second inorganic filler. In Examples 5 and 6, furthermore, the resolution of the photosensitive insulating paste, the dielectric constant of the inductor component, and effectiveness in crack prevention were all especially good.

In Comparative Example 1, a photosensitive insulating paste that contained only the glass frit was used. In Comparative Example 1, resolution and dielectric constant were good, but effectiveness in crack prevention was rated as x. In Comparative Example 2, a photosensitive insulating paste that contained both the first inorganic filler and the second inorganic filler in an amount of 40% by volume was used. This comparative example, however, was rated as x for all of resolution, dielectric constant, and effectiveness in crack prevention, presumably because, in Comparative Example 2, the percentage of the glass frit was low due to high percentages of the first inorganic filler and the second inorganic filler, resulting in brittleness of the formed insulating layers. In Comparative Example 3, the photosensitive insulating paste was formed with the amount of the first inorganic filler set to 50% by volume and that of the second inorganic filler to 30% by volume, although the percentage of the glass frit was 20% by volume, the same as in Comparative Example 2. The ratings for resolution and dielectric constant were good, but the rating for effectiveness in crack prevention was x. This is presumably because the percentage of the glass frit was not in an appropriate range.

Overall, it was found that by using a photosensitive insulating paste that contains the glass frit, the first inorganic filler, and the second inorganic filler within respective appropriate ranges, good results are obtained for all of resolution, dielectric constant, and effectiveness in crack prevention.

It should be noted that the present disclosure is not limited to the above embodiment, and modifications are possible without departing from the spirit of the present disclosure. The shape of the core is not limited to this embodiment, and modifications are possible. The number of coils, furthermore, is not limited to this embodiment, and modifications are possible.

The present disclosure includes the following aspects.

<1> A photosensitive insulating paste containing glass frit, a first inorganic filler, a second inorganic filler, an alkali-soluble polymer, a photosensitive monomer, a photopolymerization initiator, and a solvent. The glass frit contains SiO₂ and B₂O₃ as a base component and contains at least one of aluminum element, sodium element, or phosphorus element as a minor component. The first inorganic filler is a silicon oxide having crystallinity. The second inorganic filler contains at least one of alumina, titania, zirconia, ceria, forsterite, or an inorganic oxide pigment. The photosensitive insulating paste contains the first inorganic filler in an amount of 10% by volume or more and 40% by volume or less (i.e., from 10% by volume to 40% by volume) and the second inorganic filler in an amount of 0% by volume or more and 30% by volume or less (i.e., from 0% by volume to 30% by volume), with a total of the glass frit, the first inorganic filler, and the second inorganic filler being 100% by volume.

<2> The photosensitive insulating paste according to <1>, wherein a softening point of the glass frit is 700° C. or above and below 900° C. (i.e., from 700° C. to below 900° C.).

<3> The photosensitive insulating paste according to <1> or <2>, wherein the photosensitive insulating paste contains the first inorganic filler in an amount of 20% by volume or more and 40% by volume or less (i.e., from 20% by volume to 40% by volume) and the second inorganic filler in an amount of 0% by volume or more and 20% by volume or less (i.e., from 0% by volume to 20% by volume), with the total of the glass frit, the first inorganic filler, and the second inorganic filler being 100% by volume.

<4> The photosensitive insulating paste according to any one of <1> to <3>, wherein the photosensitive insulating paste contains the first inorganic filler in an amount of 30% by volume or more and 40% by volume or less (i.e., from 30% by volume to 40% by volume) and the second inorganic filler in an amount of 10% by volume or more and 20% by volume or less (i.e., from 10% by volume to 20% by volume), with the total of the glass frit, the first inorganic filler, and the second inorganic filler being 100% by volume.

<5> The photosensitive insulating paste according to any one of <1> to <4>, wherein the minor component of the glass frit includes the phosphorus element.

<6> The photosensitive insulating paste according to <5>, wherein the phosphorus element is contained in an amount of 0.1% by mass or more and 10% by mass or less (i.e., from 0.1% by mass to 10% by mass).

<7> An electronic component including a body; and a coil disposed inside the body and wound along an axis. The coil includes multiple coil wires. The body contains a glass material, a first inorganic filler, and a second inorganic filler. The glass material contains SiO₂ and B₂O₃ as a base component and contains at least one of aluminum element, sodium element, or phosphorus element as a minor component. The first inorganic filler is a silicon oxide having crystallinity. The second inorganic filler contains at least one of alumina, titania, zirconia, ceria, forsterite, or an inorganic oxide pigment. The body contains the first inorganic filler in an amount of 10% by volume or more and 40% by volume or less (i.e., from 10% by volume to 40% by volume) and the second inorganic filler in an amount of 0% by volume or more and 30% by volume or less (i.e., from 0% by volume to 30% by volume), with a total of the glass material, the first inorganic filler, and the second inorganic filler being 100% by volume.

<8> The electronic component according to <7>, wherein a ratio of a thickness of the coil wires in a direction along the axis to a thickness of portions of the body between adjacent ones of the coil wires in the direction along the axis is in a range of 1.0 or greater and 3.0 or less (i.e., from 1.0 to 3.0).

<9> The electronic component according to <7> or <8>, wherein an average of a thickness of the coil wires in a direction along the axis is 3 μm or more and 15 μm or less (i.e., from 3 μm to 15 μm).

<10> The electronic component according to any one of <7> to <9>, wherein the number of windings of the coil wires is one or more loops.

What is claimed is:

1. A photosensitive insulating paste comprising:
glass frit, a first inorganic filler, a second inorganic filler, an alkali-soluble polymer, a photosensitive monomer, a photopolymerization initiator, and a solvent, wherein:
the glass frit contains SiO₂ and B₂O₃ as a base component and contains at least one of aluminum element, sodium element, or phosphorus element as a minor component;
the first inorganic filler is a silicon oxide having crystallinity;
the second inorganic filler contains at least one of alumina, titania, zirconia, ceria, forsterite, or an inorganic oxide pigment; and
the photosensitive insulating paste contains the first inorganic filler in an amount of from 10% by volume to 40% by volume and the second inorganic filler in an amount of from 0% by volume to 30% by volume, with a total of the glass frit, the first inorganic filler, and the second inorganic filler being 100% by volume.

2. The photosensitive insulating paste according to claim 1, wherein:
a softening point of the glass frit is from 700° C. to below 900° C.

3. The photosensitive insulating paste according to claim 1, wherein:
the photosensitive insulating paste contains the first inorganic filler in an amount of from 20% by volume to 40% by volume and the second inorganic filler in an amount of from 0% by volume to 20% by volume, with the total of the glass frit, the first inorganic filler, and the second inorganic filler being 100% by volume.

4. The photosensitive insulating paste according to claim 1, wherein:
the photosensitive insulating paste contains the first inorganic filler in an amount of from 30% by volume to 40% by volume and the second inorganic filler in an amount of from 10% by volume to 20% by volume, with the total of the glass frit, the first inorganic filler, and the second inorganic filler being 100% by volume.

5. The photosensitive insulating paste according to claim 1, wherein:
the minor component of the glass frit includes the phosphorus element.

6. The photosensitive insulating paste according to claim 5, wherein:
the phosphorus element is contained in an amount of from 0.1% by mass to 10% by mass.

7. The photosensitive insulating paste according to claim 2, wherein:
the photosensitive insulating paste contains the first inorganic filler in an amount of from 20% by volume to 40% by volume and the second inorganic filler in an amount of from 0% by volume to 20% by volume, with the total of the glass frit, the first inorganic filler, and the second inorganic filler being 100% by volume.

8. The photosensitive insulating paste according to claim 2, wherein:
the photosensitive insulating paste contains the first inorganic filler in an amount of from 30% by volume to 40% by volume and the second inorganic filler in an amount of from 10% by volume to 20% by volume, with the total of the glass frit, the first inorganic filler, and the second inorganic filler being 100% by volume.

9. The photosensitive insulating paste according to claim 2, wherein:
the minor component of the glass frit includes the phosphorus element.

10. The photosensitive insulating paste according to claim 9, wherein:
the phosphorus element is contained in an amount of from 0.1% by mass to 10% by mass.

11. An electronic component comprising:
a body; and
a coil disposed inside the body and wound along an axis, wherein:
the coil includes a plurality of coil wires;
the body contains a glass material, a first inorganic filler, and a second inorganic filler;
the glass material contains SiO₂ and B₂O₃ as a base component and contains at least one of aluminum element, sodium element, or phosphorus element as a minor component;
the first inorganic filler is a silicon oxide having crystallinity;
the second inorganic filler contains at least one of alumina, titania, zirconia, ceria, forsterite, or an inorganic oxide pigment; and
the body contains the first inorganic filler in an amount of from 10% by volume to 40% by volume and the second inorganic filler in an amount of from 0% by volume to 30% by volume, with a total of the glass material, the first inorganic filler, and the second inorganic filler being 100% by volume.

12. The electronic component according to claim 11, wherein:
a ratio of a thickness of the coil wires in a direction along the axis to a thickness of portions of the body between adjacent ones of the coil wires in the direction along the axis is in a range of from 1.0 to 3.0.

13. The electronic component according to claim 11, wherein:
an average of a thickness of the coil wires in a direction along the axis is from 3 μm to 15 μm.

14. The electronic component according to claim 12, wherein:
an average of a thickness of the coil wires in a direction along the axis is from 3 μm to 15 μm.

15. The electronic component according to claim 11, wherein:
a number of windings of the coil wires is one or more loops.

16. The electronic component according to claim 12, wherein:
a number of windings of the coil wires is one or more loops.
